(19) United States
(12) Patent Application Publication
(10) Pub. No.: US 2012/0056795 A1
(43) Pub. Date: Mar. 8, 2012

(54) ANTENNA MATCHING CIRCUIT, ANTENNA DEVICE, AND METHOD OF DESIGNING ANTENNA DEVICE

(75) Inventors: Shoji NAGUMO, Nagaokakyo-shi (JP); Hiromasa KOYAMA, Nagaokakyo-shi (JP); Noriyuki UEKI, Nagaokakyo-shi (JP)

(73) Assignee: MURATA MANUFACTURING CO., LTD., Kyoto-fu (JP)

(21) Appl. No.: 13/241,094

(22) Filed: Sep. 22, 2011

Related U.S. Application Data
(63) Continuation of application No. PCT/JP2009/069903, filed on Nov. 26, 2009.

(30) Foreign Application Priority Data
Apr. 1, 2009 (JP) 2009-089186

(51) Int. Cl. H01Q 1/50; H03H 7/38; H01P 11/00; H01Q 1/00

(52) U.S. Cl. 343/787; 343/860; 333/32; 29/600

(57) ABSTRACT

A switching function and multiband compatibility and a function handling deviation of matching caused by the influence of the human body are configured in a single matching circuit. An antenna matching circuit is formed by a reactance changing section and a matching section. The matching section is formed by a parallel circuit of an inductor and a capacitor, and the LC parallel circuit is shunt-connected between a feed section and the ground. The reactance changing section changes the resonant frequency to be compatible with a plurality of bands, and performs fine adjustment of the resonant frequency changed by the influence of the human body. The parallel inductor causes the locus of input impedance of the antenna matching circuit to draw a small circle locus in the first quadrant of a Smith chart. The parallel capacitor is adjustable to move the small circle locus to the center on the Smith chart.

### CROSS REFERENCE TO RELATED APPLICATIONS

The present application is a continuation of International Application No. PCT/JP2009/069903 filed Nov. 26, 2009, which claims priority to Japanese Patent Application No. 2009-089186 filed Apr. 1, 2009, the entire contents of each of these applications being incorporated herein by reference in their entirety.

### TECHNICAL FIELD

The present invention relates to a matching circuit of an antenna provided to, for example, a cellular phone terminal, an antenna device, and a method of designing an antenna device.

### BACKGROUND

As the performance of an antenna device for a mobile radio terminal such as a cellular phone terminal, “compactness and multiband compatibility” and “reduction of the influence of the human body” are required.

“Compactness and multiband compatibility” is also expressed by a word “reconfigurable.” “Reconfigurable” means the adjustment of the resonant frequency of an antenna to the target frequency band and the pursuit of compactness and multiband compatibility. Providing a frequency changeover switch, a tunable circuit, or the like corresponds thereto.

Meanwhile, “reduction of the influence of the human body” is also expressed by a word “adjustable” or “adaptive.” That is, “adjustable” or “adaptive” means the correction of matching between an antenna and a feed circuit (=input impedance of the antenna) deviated by the influence of the human hand or body and the pursuit of a better VSWR (voltage standing wave ratio) under an environment subjected to the influence of the human hand or body.

With this “adjustability” or “adaptivity,” it is intended not only to reduce the mere reflection loss of the antenna (=reflection without radiation) but also to reduce the transmission loss of a subsequent-stage device (with both the in- and out-side portions normally designed for 50Ω, the transmission loss is increased by the connection of a load substantially deviating from 50Ω). Further, it is intended to configure an AMP to output higher power from the perspective of a load map.

As to an antenna intended to cover a plurality of frequency bands, Japanese Unexamined Patent Application Publication No. 2007-235635 (Patent Document 1) is disclosed. Herein, a configuration of a multifrequency resonant antenna of Patent Document 1 will be described with reference to FIG. 1.

In FIG. 1, the multifrequency resonant antenna is formed by matching circuits 2 and 3, an impedance adjusting circuit 4, an antenna element 5, and switches 6 to 8, and is connected to a radio circuit 1.

The switch 6 performs a switching operation to cause electrical conduction or non-conduction between the antenna element 5 and the matching circuit 2. The switch 7 performs a switching operation to electrically connect the antenna element 5 to the matching circuit 3 or the impedance adjusting circuit 4. The switch 8 performs a switching operation to electrically connect the radio circuit 1 to the matching circuit 2 or the matching circuit 3.

For the antenna element 5, therefore, a first feed path is formed by the connection of the radio circuit 1 to the switch 8, the matching circuit 2, and the switch 6, and a second feed path is formed by the connection of the radio circuit 1 to the switch 8, the matching circuit 3, and the switch 7.

The electrical length of the antenna element as viewed from the switch 6 forms a λ/4 antenna at a frequency fa, and the electrical length of the antenna element as viewed from the switch 7 forms a λ/4 antenna at a frequency fb.

As to a configuration which changes the element length of the antenna element in accordance with the frequency band to be used, Japanese Unexamined Patent Application Publication No. 2008-113233 (Patent Document 3) is disclosed.

Meanwhile, Japanese Unexamined Patent Application Publication No. 61-135235 (Patent Document 2) discloses a configuration which detects the matching deviated by the influence of the human body and performs a feedback control on a variable matching circuit provided directly under an antenna element (radiation electrode), to thereby search for a better matching state. In Patent Document 2, the variable capacitance in the variable matching circuit is controlled. Further, a configuration provided with a plurality of matching circuits in place of the variable matching circuit is disclosed in Japanese Unexamined Patent Application Publication No. 2004-304521 (Patent Document 4).

### SUMMARY

Embodiments of the present disclosure provide an antenna matching circuit including a switching function for multiband compatibility and a function handling the deviation of matching caused by the influence of the human body, an antenna device including the same, and a method of designing the antenna device.

In one aspect of the disclosure, a method of designing an antenna device, which includes an antenna element and an antenna matching circuit connected between the antenna element and a feed section, includes forming the antenna matching circuit with a reactance changing section connected to a base portion of the antenna element and a matching section connected between the feed section and the reactance changing section; and forming the matching section with a parallel inductor and a parallel capacitor each shunt-connected between the feed section and ground. The reactance changing section is switchable to one of plural resonant frequencies to be compatible with respective plural frequency bands, and finely adjustable in response to a change in the resonant frequency caused by the influence of the human body. The parallel inductor is set to cause the locus of impedance as viewed from the feed section toward the antenna matching circuit to draw a small circle locus in substantially the first quadrant of a Smith chart. The capacitance of the parallel capacitor is adjustable to move the small circle locus to the center on the Smith chart.

In another aspect of the disclosure, an antenna matching circuit connected between an antenna element and a feed section includes a reactance changing section connected to a base portion of the antenna element and a matching section connected between the feed section and the reactance changing section. The matching section is formed by a parallel inductor and a parallel capacitor each shunt-connected between the feed section and ground. The reactance changing section is adapted to set a reactance value to switch the resonant frequency to be compatible with a plurality of frequency bands and perform fine adjustment of the resonant frequency in response to a change by the influence of a human body. The parallel inductor is set to a value for having the locus of impedance as viewed from the feed section toward the antenna matching circuit draw a small circle locus in substantially the first quadrant of a Smith chart. The parallel capacitor is adjustable to set a capacitance value for moving the small circle locus to the center on the Smith chart.

In a more specific embodiment, the reactance changing section may be an LC resonant circuit of a fixed inductor and a variable capacitor.

In another more specific embodiment, some or all of circuit elements forming the antenna matching circuit may be packaged on or in a laminated board.

In another aspect of the disclosure, an antenna device includes an antenna matching circuit having one of the abovementioned configurations and the antenna element.

In a more specific embodiment, the antenna element may be formed by a dielectric or magnetic substrate and an antenna element electrode disposed on a surface of the substrate or inside the substrate.

In another more specific embodiment, the antenna matching circuit may be included in the substrate.

In yet another more specific embodiment, the antenna element may be an antenna element having favorable radiation Q alone as the antenna element, among plural types of antenna elements connectable to an antenna connecting section of the antenna matching circuit.

In another more specific embodiment, a selection condition of the plural types of antenna elements may be one or various combinations of a plurality of the position of a feed point for the antenna element, the interval between the antenna element and the ground facing the antenna element, and the size of the antenna element.

### BRIEF DESCRIPTION OF DRAWINGS

FIG. 1 is a diagram illustrating a configuration of a multifrequency resonant antenna of Patent Document 1.

FIG. 2A is an exploded perspective view illustrating a configuration of an antenna matching circuit and an antenna device according to a first exemplary embodiment. FIG. 2B is a diagram illustrating, in a circuit diagram, a portion corresponding to the antenna matching circuit in FIG. 2A. FIG. 2C is a circuit diagram of the antenna device of the first exemplary embodiment.

FIGS. 3A and 3B are diagrams illustrating characteristics of the antenna matching circuit switched to the low-band side. FIG. 3A is a diagram illustrating, on a Smith chart, impedance as viewed from a feed section toward the antenna matching circuit. FIG. 3B is a frequency characteristic diagram of return loss.

FIGS. 4A and 4B are diagrams illustrating characteristics of the antenna matching circuit switched to the high-band side. FIG. 4A is a diagram illustrating, on a Smith chart, input impedance as viewed from the feed section toward the antenna matching circuit. FIG. 4B is a frequency characteristic diagram of return loss.

FIG. 5 is a diagram illustrating a method of causing an inductor and a capacitor of a matching section to move a locus from a predetermined quadrant toward the center on a Smith chart.

FIGS. 6A and 6B are diagrams illustrating a state in which, for a low band, a small circle locus is moved from the first quadrant to the center on a Smith chart. FIG. 6A is a diagram illustrating, on the Smith chart, impedance as viewed from the feed section toward the antenna matching circuit. FIG. 6B is a frequency characteristic diagram of return loss.

FIGS. 7A and 7B are diagrams illustrating a state in which, for a high band, a small circle locus is moved from the first quadrant to the center on a Smith chart. FIG. 7A is a diagram illustrating, on the Smith chart, impedance as viewed from the feed section toward the antenna matching circuit. FIG. 7B is a frequency characteristic diagram of return loss.

FIGS. 8A to 8C are diagrams illustrating the action of the inductor of the matching section. FIG. 8A is a perspective view of a state in which the resonant frequency of an antenna element is set to a high band, and the antenna matching circuit is provided only with the inductor of the matching section. FIG. 8B is a diagram illustrating, on a Smith chart, impedance as viewed from the feed section toward the antenna matching circuit. FIG. 8C is a frequency characteristic diagram of return loss.

FIG. 9A is a perspective view illustrating a state in which pseudo phantoms PB, PF, and PH are brought into proximity to the antenna device 101. FIG. 9B is a front view thereof.

FIGS. 10A and 10B are diagrams illustrating how the proximity of the human body affects the behavior of a small circle locus formed in the first quadrant of a Smith chart in accordance with single resonant matching by the inductor (parallel L) of the matching section. FIG. 10A is a diagram illustrating, on the Smith chart, impedance as viewed from the feed section toward the antenna matching circuit. FIG. 10B is a frequency characteristic diagram of return loss.

FIGS. 11A to 11C are diagrams for explaining, in an equivalent circuit, the phenomenon caused by the influence of the human body.

FIG. 12A is a diagram illustrating impedance loci on a Smith chart in the equivalent circuit illustrated in FIGS. 11A to 11C. FIG. 12B is a diagram illustrating return losses thereof.

FIG. 13A is an exploded perspective view of an antenna device according to a second exemplary embodiment. FIG. 13B is an exploded perspective view of another antenna device according to the second exemplary embodiment.

FIGS. 14A and 14B illustrate examples of application of the antenna matching circuit described in the first exemplary embodiment to the antennas illustrated in FIGS. 13A and 13B.

FIG. 15 is a diagram illustrating return losses and efficiencies of the respective antennas obtained after the application of the antenna matching circuit.

FIGS. 16A to 16D are diagrams illustrating the results of simulations, for the two types of antennas, of the intensity distribution of surface current flowing through a housing.

FIG. 17 is an exploded perspective view illustrating a configuration of an antenna device according to a third exemplary embodiment.

FIG. 18A is an exploded perspective view of an antenna device according to a fourth exemplary embodiment. FIG. 18B is an exploded perspective view of another antenna device according to the fourth exemplary embodiment.

FIGS. 19A to 19C are exploded perspective views of three other antenna devices according to the fourth exemplary embodiment.

FIG. 20 is an exploded perspective view of an antenna device according to a fifth exemplary embodiment.

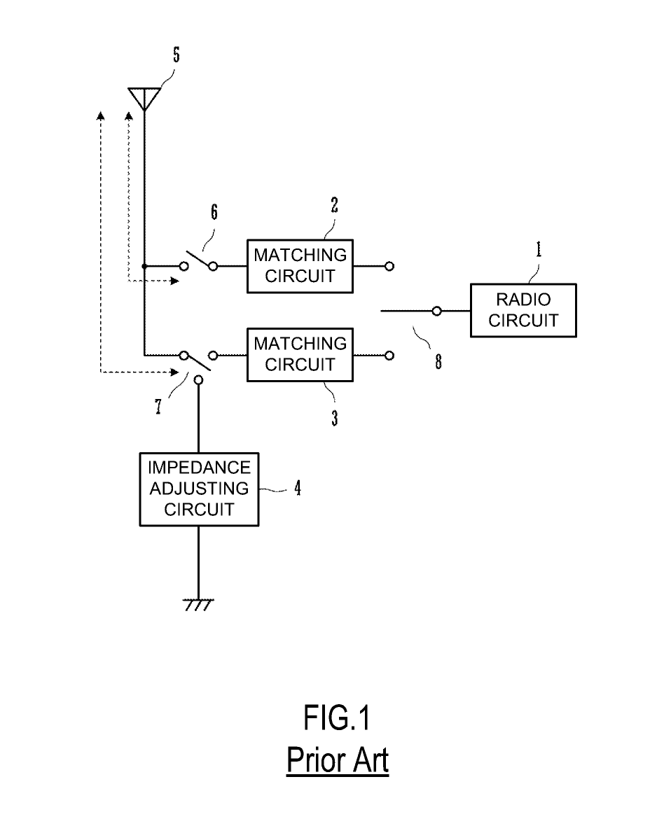

### DETAILED DESCRIPTION

With respect to the antenna disclosed in Patent Document 1, the inventors realized the following. The optimal states of the matching circuits for respective frequency bands are different, and therefore the respective matching circuits are formed by the switching between the paths. In this Patent Document 1, only the perspective of reconfigurability is present, and the perspective of adjustability is absent. Further, the matching circuits are illustrated only in a block diagram, and no specific circuitry (architecture) is disclosed. The perspective of expansion of the band, such as dual resonance, for example, is absent. Further, the presence of two paths and circuits prevents a reduction in space. That is, the perspective of compactness is also absent.

With respect to the antenna disclosed in Patent Document 2, the inventors realized that the perspective of adaptation to a plurality of frequency bands is absent. That is, only the perspective of adjustability is present, and the perspective of reconfigurability is absent. Further, the circuit for the adjustable function disclosed in Patent Document 2 is mainly formed by the combination of variable and invariable elements based on the n-type or T-type structure, and thus the number of required discrete elements is large.

As described above, in the related art, reconfigurability and adjustability are viewed as separate issues in terms of the circuit, and there is no circuitry integrating these functions. This is considered to be due to a high level of difficulty of the circuit architecture sharing or serving these functions.

The circuitry for the adjustable function is also desired to be as simple as possible in view of the transmission loss and cost. If the movement on the Smith chart is scrutinized, as in the present disclosure, it is possible to reduce the number of discrete elements and realize a simple configuration while serving both the reconfigurable and adjustable functions.

In light of the above, the present disclosure provides an antenna matching circuit in which a switching function for compactness and multiband compatibility (reconfigurable function) and a function handling the deviation of matching caused by the influence of the human body (adjustable function) are simply configured in a single matching circuit, an antenna device including the same, and a method of designing the antenna device.

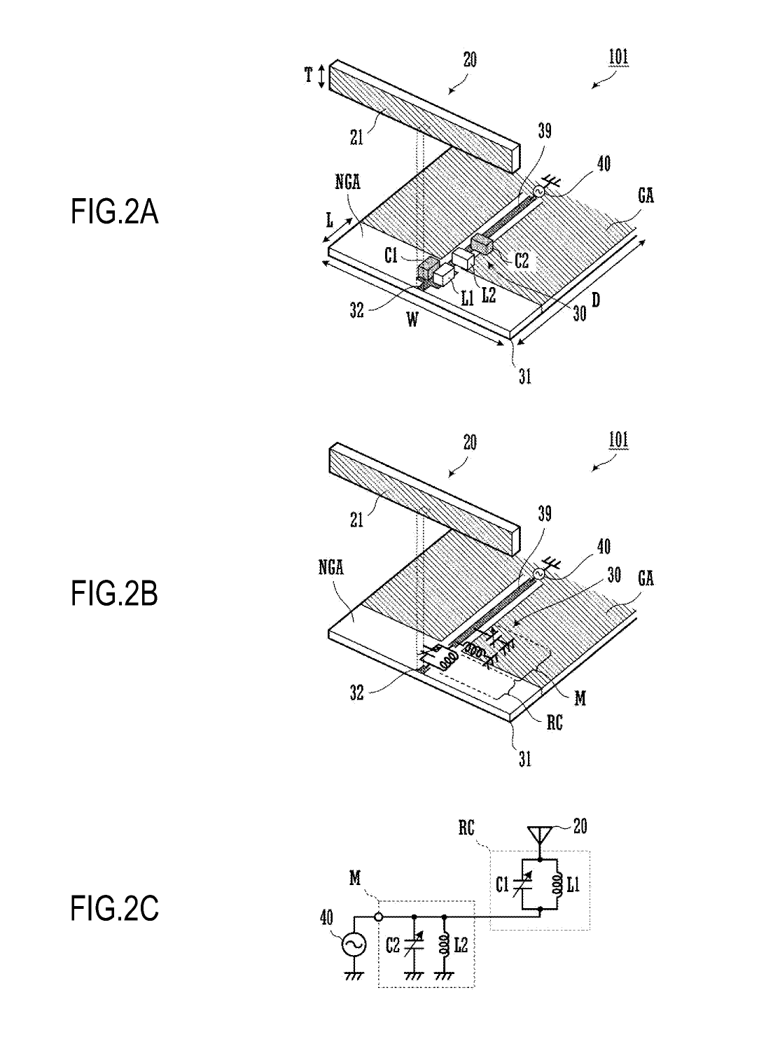

FIG. 2A is a perspective view illustrating a configuration of an antenna matching circuit and an antenna device according to a first exemplary embodiment. A circuit board (hereinafter simply referred to as “board”) 31 is provided with a ground area GA and a non-ground area NGA, and an antenna matching circuit 30 is formed on the board 31. Further, an antenna element 20 formed with an antenna element electrode 21 is mounted on the non-ground area NGA of the board 31, to thereby form an antenna device 101.

FIG. 2B illustrates, in a circuit diagram, a portion corresponding to the antenna matching circuit 30 in FIG. 2A. Further, FIG. 2C is a circuit diagram of the antenna device 101.

In FIG. 2A, the dimension of the non-ground area NGA of the board 31 indicated by a sign W in the drawing is 40 mm, the dimension indicated by a sign L is 4 mm, and the dimension indicated by a sign D is 80 mm. Further, the dimension of the antenna element 20 indicated by a sign T is 3 mm, and the length of the antenna element 20 is equal to W.

The antenna matching circuit 30 is formed between an antenna connecting section 32, to which the antenna element 20 is connected, and a feed section 39. This antenna matching circuit 30 is formed by a reactance changing section RC and a matching section M. The reactance changing section RC is formed by a parallel circuit of an inductor L1 and a capacitor C1, and the LC parallel circuit is connected in series to a base portion of the antenna element 20. The matching section M is formed by a parallel circuit of an inductor L2 (parallel inductor of the present disclosure) and a capacitor C2 (parallel capacitor of the present disclosure), and the LC parallel circuit is shunt-connected between a feed circuit 40 and the reactance changing section RC.

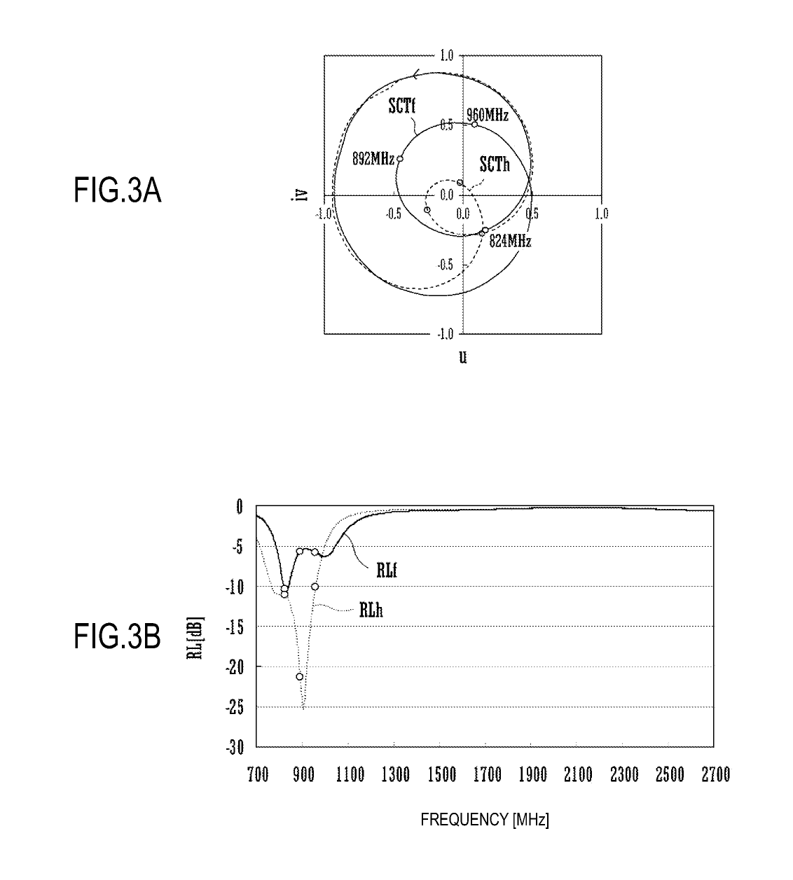

FIGS. 3A and 3B are diagrams illustrating characteristics of the antenna matching circuit in which the reactance changing section RC and the matching section M are switched (adapted) for a low band. FIG. 3A is a diagram illustrating, on a Smith chart, input impedance as viewed from the feed section 39 toward the antenna matching circuit. FIG. 3B is a frequency characteristic diagram of return loss.

An impedance locus on the Smith chart at a frequency from 700 MHz to 2700 MHz in this case is represented by a locus SCTf. Further, the return loss in this case is a characteristic represented by a curve RLf in FIG. 3B. The return loss is thus secured in a low frequency band having a center frequency of 900 MHz.

To obtain an optimal matching state in a state in which the antenna device 101 illustrated in FIGS. 2A to 2C is installed in, for example, a cellular phone terminal and a human head comes into proximity of the antenna device or a hand holding the cellular phone terminal further covers the antenna device (hereinafter referred to as “human body proximity state”), the capacitor C1 of the reactance changing section RC and the capacitor C2 of the matching section M are made variable. With this configuration, the impedance locus is reduced in size of a small circle (small loop) thereof, and moves to a central portion of the Smith chart, as indicated by a locus SCTh in FIG. 3A. As a result, a sufficient return loss characteristic is obtained in the 900 MHz band, as indicated by a return loss RLh in FIG. 3B.

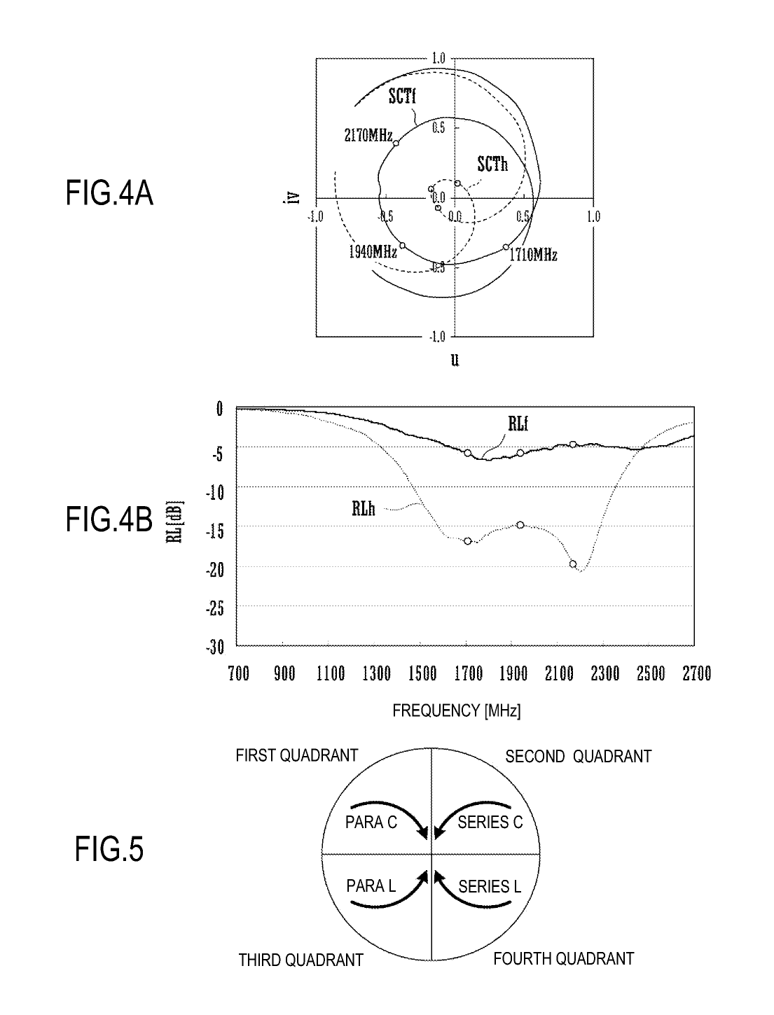

FIGS. 4A and 4B are diagrams illustrating characteristics of the antenna matching circuit in which the reactance changing section RC and the matching section M are switched (adapted) to the high-band side. FIG. 4A is a diagram illustrating, on a Smith chart, input impedance as viewed from the feed section 39 toward the antenna matching circuit. FIG. 4B is a frequency characteristic diagram of return loss.

An impedance locus on the Smith chart at a frequency from 700 MHz to 2700 MHz in this case is represented by a locus SCTf. Further, the return loss in this case is a characteristic represented by a curve RLf in FIG. 4B. The return loss is thus secured in a high frequency band centering on 1900 MHz.

To obtain an optimal matching state in the human body proximity state of the antenna device 101, the capacitor C2 of the matching section M is made variable. With this configuration, the impedance locus is reduced in size of a loop (small circle) thereof, and moves to a central portion of the Smith chart, as indicated by a locus SCTh in FIG. 4A. As a result, a sufficient return loss characteristic is obtained in a high band centering on 1900 MHz, as indicated by a return loss RLh in FIG. 4B.

As described in detail later, the reactance changing section RC sets the resonant frequency of the antenna to a predetermined value by adding reactance to the initial reactance value possessed by the antenna element 20. With the adjustment of the value of the capacitor C1 of this reactance changing section RC, the resonant frequency changed by the influence of the human body is also finely adjusted.

FIG. 5 is an explanatory diagram illustrating a state in which a locus is moved from a predetermined quadrant toward the center on a Smith chart by the inductor L2 and the capacitor C2 of the matching section M.

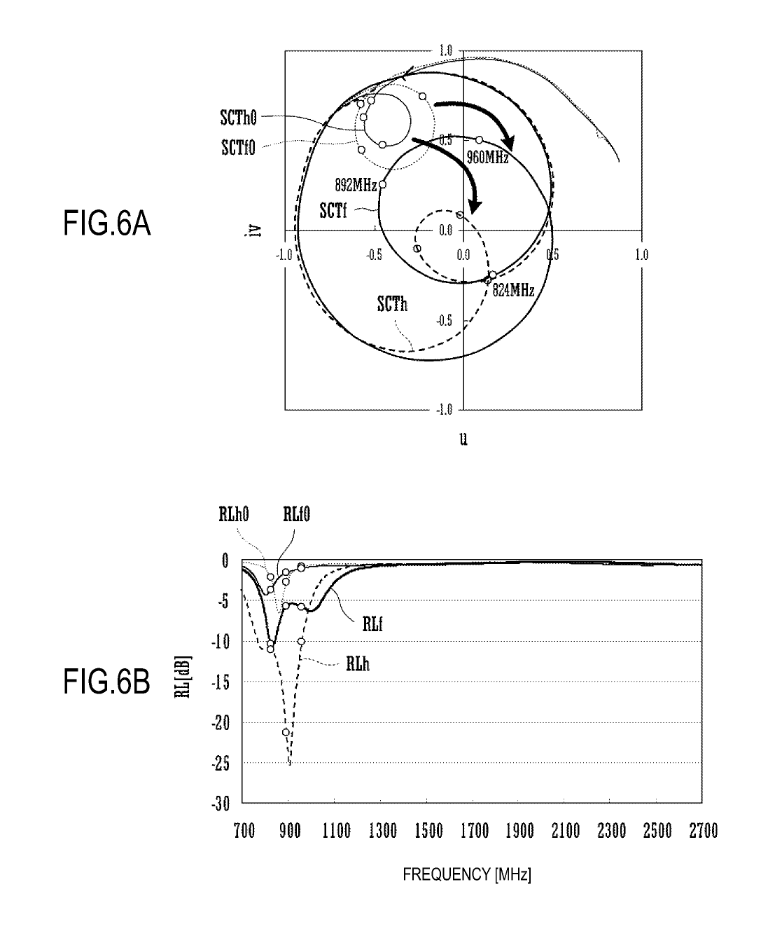

FIGS. 6A and 6b are diagrams illustrating the action of the capacitor C2 of the matching section M. FIG. 6A is a diagram illustrating, on a Smith chart, impedance as viewed from the feed section 39 toward the antenna matching circuit. FIG. 6B is a frequency characteristic diagram of return loss.

A major feature of the antenna matching circuit of the present disclosure lies in that the small circle locus is basically moved by the capacitor C2 of the matching section M from the first quadrant to the proximity of the center (50Ω) of the Smith chart, and that (1) the transition of the state from “absence” to “presence” of the influence of the human body and (2) the expansion of the band at the time of switching of the frequency band are covered by a common (shared) architecture. The reason for the ability of the common architecture (=circuitry) to cover both (1) and (2) will be described later.

FIG. 6A illustrates a state in which, for a low band, a small circle locus is moved from the first quadrant to the center on a Smith chart. In FIG. 6A, a small circle locus SCTf0 represents an impedance locus in a free state, and a small circle locus SCTh0 represents an impedance locus in the human body proximity state. Further, a small circle locus SCTf represents a small circle locus obtained after the movement of the small circle locus SCTf0 by the capacitor C2 of the matching section M. A small circle locus SCTh represents a small circle locus obtained after the movement of the small circle locus SCTh0 by the capacitor C2 of the matching section M.

As described later, the influence of the human body acts such that the size of the small circle locus in the first quadrant of the Smith chart is reduced at the position.

In FIG. 6B, a curve RLf0 represents a return loss corresponding to the small circle locus SCTf0, and a curve RLh0 represents a return loss corresponding to the small circle locus SCTh0. Further, a curve RLf represents a return loss corresponding to the small circle locus SCTf, and a curve RLh represents a return loss corresponding to the small circle locus SCTh.

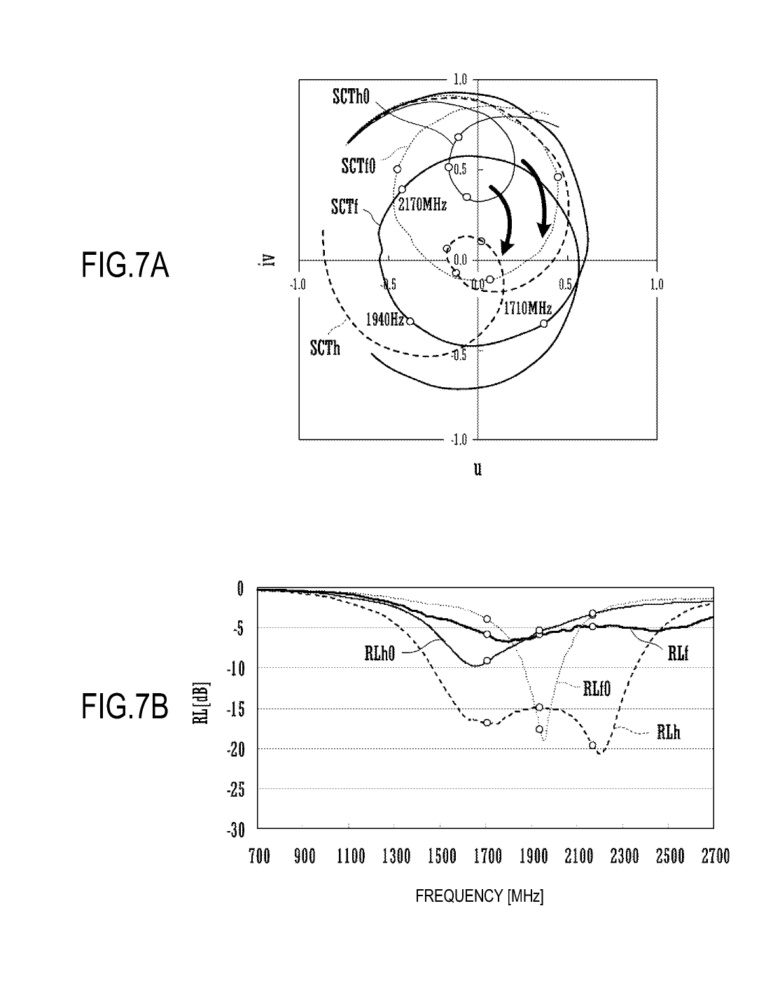

FIG. 7A illustrates a state in which, for a high band, a small circle locus is moved from the first quadrant to the center on a Smith chart. In FIG. 7A, a small circle locus SCTf0 represents an impedance locus in a free state, and a small circle locus SCTh0 represents an impedance locus in the human body proximity state. Further, a small circle locus SCTf represents a small circle locus obtained after the movement of the small circle locus SCTf0 by the capacitor C2 of the matching section M. A small circle locus SCTh represents a small circle locus obtained after the movement of the small circle locus SCTh0 by the capacitor C2 of the matching section M.

In FIG. 7B, a curve RLf0 represents a return loss corresponding to the small circle locus SCTf0, and a curve RLh0 represents a return loss corresponding to the small circle locus SCTh0. Further, a curve RLf represents a return loss corresponding to the small circle locus SCTf, and a curve RLh represents a return loss corresponding to the small circle locus SCTh.

The small circle locus SCTh0, which extends over not only the first quadrant but also the second quadrant, approaches a central portion of the Smith chart owing to the action of the capacitor C2 (parallel C) of the matching section M. The inductor L2 (parallel inductor) of the matching section M causes the locus of impedance as viewed from the feed section toward the antenna matching circuit to draw a small circle locus in substantially the first quadrant of the Smith chart. The small circle locus may be located at a position to which the small circle locus is moved toward the central portion of the Smith chart by the parallel C. That is, this is the meaning of “substantially” in the aforementioned “substantially the first quadrant.”

In this manner, the inductor L2 of the matching section M is caused to draw the small circle of the impedance locus (small circle later rotating in the proximity of the center on the Smith chart), and the capacitor C2 of the matching section M is caused to move the rotation of the locus including the small circle from the first quadrant of the Smith chart to the proximity of the center (50Ω) on the Smith chart. That is, the impedance locus on the Smith chart generated by the change in frequency draws the small circle at the center of the Smith chart. This indicates that the matching section M forms an impedance circuit in which the return loss characteristic as viewed from the feed section toward the antenna connecting section is multi-resonant in a predetermined frequency band.

As described later, the inductor L2 of the matching section M has an action of converting the impedance locus into a small circle and placing the impedance locus in the first quadrant of the Smith chart. The optimal value of this inductor L2, which is different between a low-band resonant system and a high-band resonant system, is fixed to an intermediate (compromising) value therebetween to save switching between the low band and the high band as much as possible.

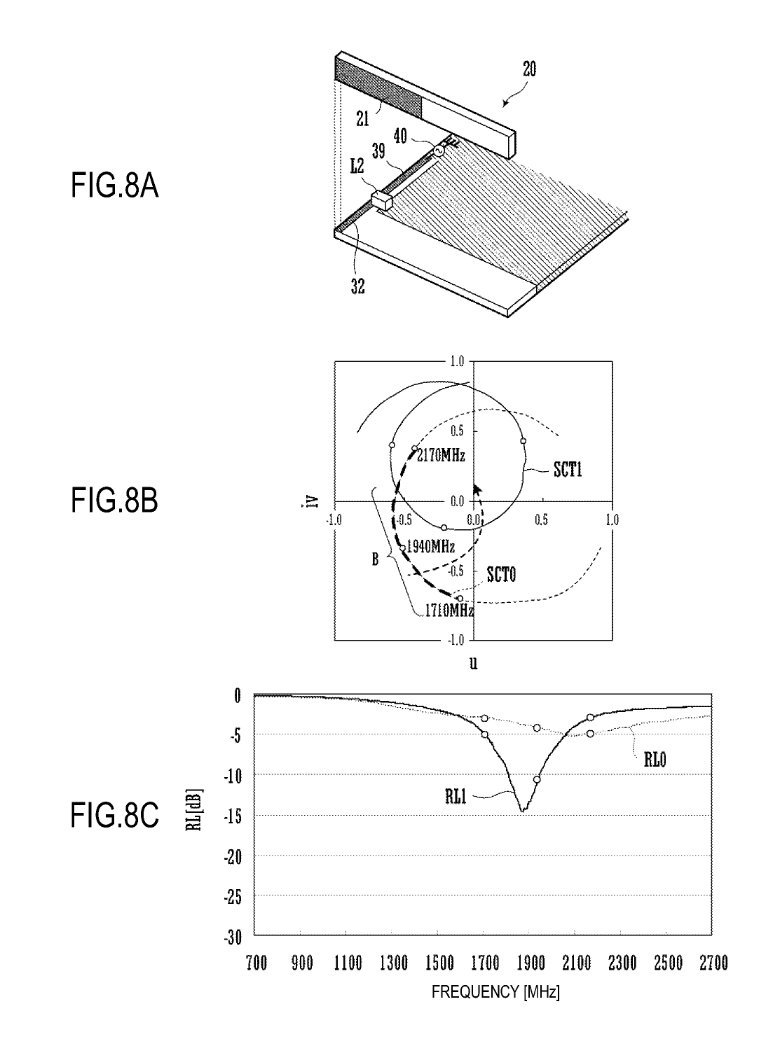

FIGS. 8A to 8C are diagrams illustrating the action of the inductor L2 (parallel inductor) of the matching section M. FIG. 8A is a perspective view of a state in which the resonant frequency of the antenna element 20 is set to a high band, and the antenna matching circuit is provided only with the inductor L2 of the matching section. FIG. 8B is a diagram illustrating, on a Smith chart, impedance as viewed from the feed section 39 toward the antenna matching circuit. FIG. 8C is a frequency characteristic diagram of return loss.

Another feature of the circuit architecture of the present disclosure is that the impedance locus on the Smith chart is converted into a small circle and placed in the first quadrant on the Smith chart. As described in detail later, when the influence of the human body is received, the influence of the human body acts to further reduce the size of the small circle in the first quadrant (initial position) in both the low band and the high band. Therefore, this is advantageous when the center on the Smith chart is aimed at by the capacitor C2 of the matching section M.

The antenna element electrode 21 of the antenna element 20, which has a length of λ/4 (integral multiple thereof), also uses the radiation by housing current (as an image or as one half of a dipole). The antenna element electrode 21 can be regarded as a so-called pseudo dipole formed by an antenna and a housing. The input impedance of a λ/2 dipole is 73.1+j42.6. Thus, the input impedance of an antenna element having an antenna length of λ/4 corresponding to half the length of the dipole is originally less than 50Ω, which is the standard in circuit design (=feed point). Further, the input impedance of the antenna element is further reduced in, for example, a structure having the electrode of the antenna element folded back and projecting toward the housing or a structure having a dielectric loaded between the antenna element and the housing.

As described above, the matching can be performed on the antenna element originally having low input impedance. Therefore, the matching can be naturally performed by a parallel L (for the 50Ω feed point), and the initial position on the Smith chart can be located in the first quadrant. In dual resonant matching in a free space, therefore, the center can be aimed at from the first quadrant of the Smith chart by the capacitor C2 of the matching section M, as a result of intending to form a configuration as simple as possible.

In FIG. 8B, if the inductor L2 of the matching section is not provided, the range of frequency from 1710 to 2170 MHz of a locus SCT0 is in the first quadrant and the third quadrant on the Smith chart, and is originally located in a region lower than 50Ω. With the provision of the inductor L2 of the matching section, the locus SCT0 shifts to a small circle state, as in a locus SCT1, and moves toward the first quadrant on the Smith chart.

In the return loss, a change occurs from a return loss RL0 of a case in which the inductor L2 of the matching section is absent to a return loss RL1 of a case in which the inductor L2 of the matching section is present, as in FIG. 8C.

Although FIGS. 8A to 8C illustrate an example of a high-band monopole antenna, it has been confirmed that the same tendency is also observed in a low-band monopole antenna. Further, it has been confirmed that the same tendency is observed not only in a Non-GND type antenna in which the antenna is mounted on a non-ground area but also in an On-GND type antenna in which the antenna is mounted on a ground area.

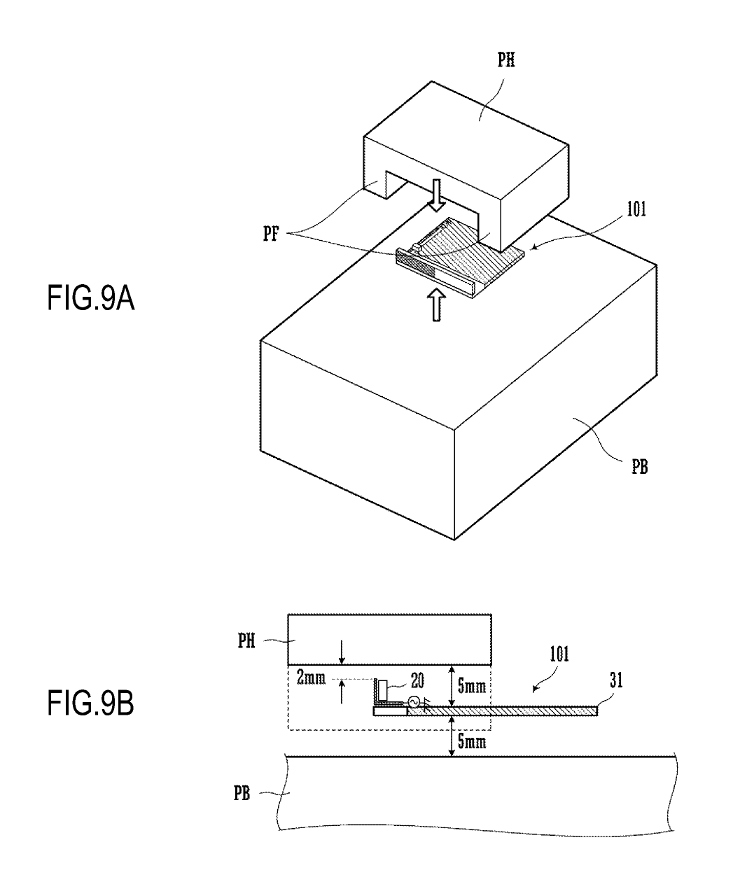

FIG. 9A is a perspective view illustrating a state in which pseudo phantoms PB, PF, and PH are brought into proximity to the antenna device 101. FIG. 9B is a front view thereof. Herein, the pseudo phantom PB is a phantom corresponding to the human head or body, the pseudo phantom PH is a phantom corresponding to the palm of a hand, and the pseudo phantom PF is a phantom corresponding to a finger. In this example, the interval between the board 31 of the antenna device 101 and each of the pseudo phantoms PH and PB is set to 5 mm, and the interval between the antenna element 20 and the pseudo phantom PH is set to 2 mm.

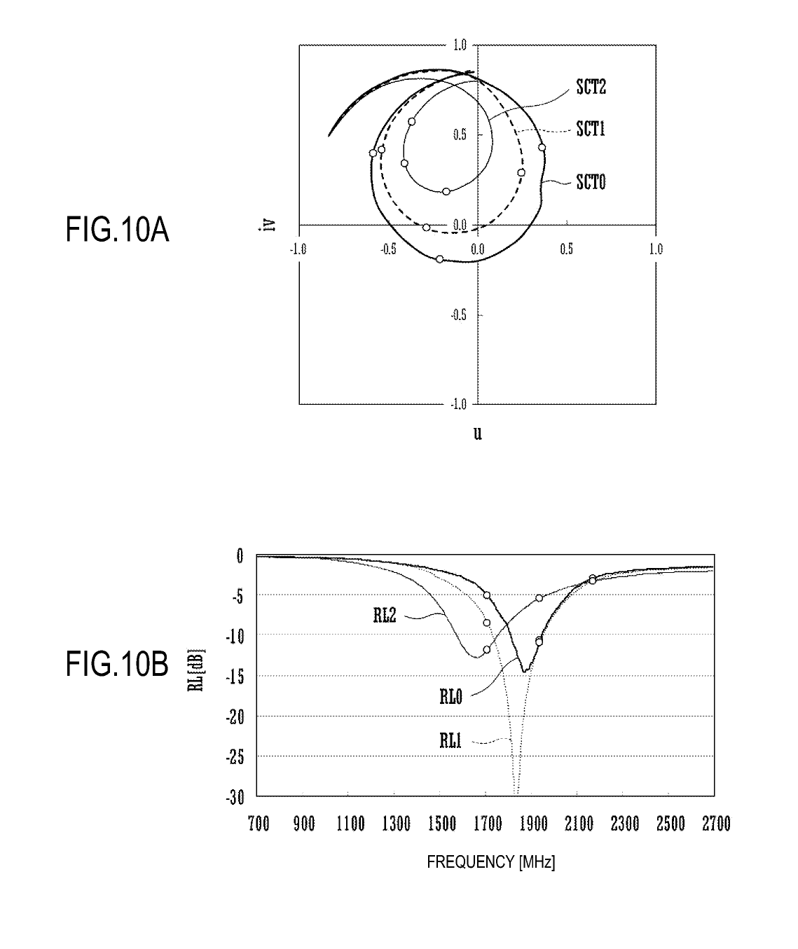

FIGS. 10A and 10B are diagrams illustrating how the proximity of the human body (two types including the proximity of the head or body and the covering by a hand are assumed) affects the behavior of a small circle locus formed in the first quadrant of a Smith chart in accordance with single resonant matching by the inductor L2 (parallel L) of the matching section M.

In FIG. 10A, a locus SCT0 represents a small circle locus in a free state, a locus SCT1 represents a small circle locus in a state in which only the pseudo phantom PB is present, and a locus SCT2 represents a small circle locus in a state in which the pseudo phantoms PH and PF (hand only) are present.

In FIG. 10B, a curve RL0 represents a return loss in the free state, a curve RL1 represents a return loss in the state in which only the pseudo phantom PB is present, and a curve RL2 represents a return loss in the state in which the pseudo phantoms PH and PF are present.

As thus illustrated, the circle of the small circle locus in the first quadrant corresponding to the initial position on the Smith chart tends to be reduced in size in accordance with the increase in the influence of the human body. Further, the degree of reduction in size of the circle is practically affected by the extent of the distance [than the difference in shape] between the antenna device and the affecting object. In other words, the size of the small circle locus simply changes in accordance with the extent of the influence of the human body.

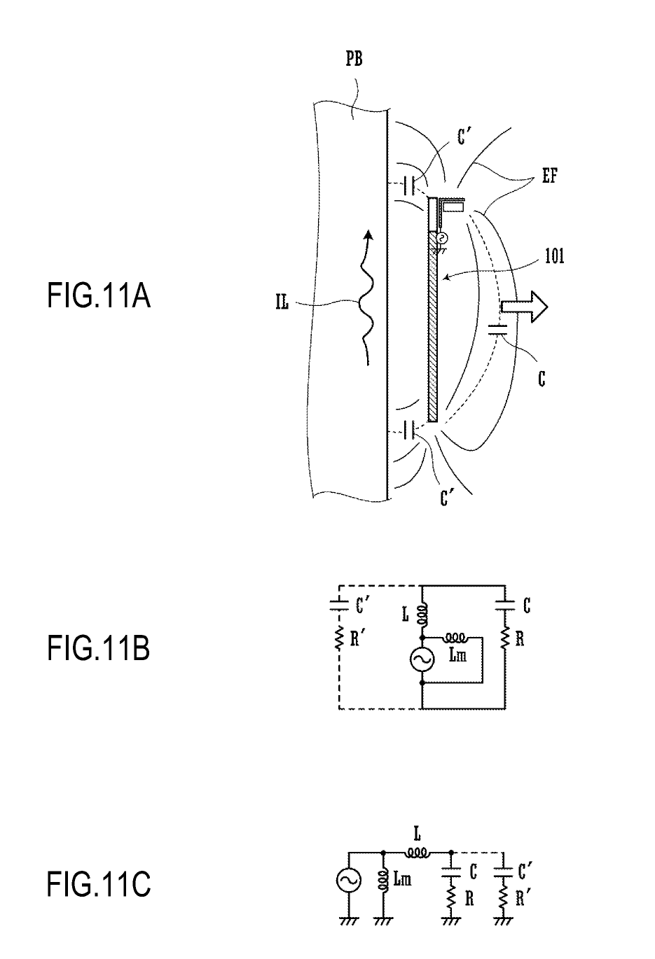

FIGS. 11A to 11C are diagrams for explaining, in an equivalent circuit, the phenomenon caused by the influence of the human body. FIG. 11A illustrates an electric force line EF generated between the antenna device 101 and the pseudo phantom PB, capacitances C and C′, and an induced current IL flowing through a medium (pseudo phantom PB).

FIG. 11B and FIG. 11C are equivalent circuit diagrams of the antenna device 101 in the state illustrated in FIG. 11A. Herein, an inductor Lm corresponds to a matching inductance (corresponding to L2 of the matching section M), an inductor L corresponds to an inductance component of an antenna radiating element, a capacitor C corresponds to a fringing [stray] capacitance, a resistor R corresponds to a radiation resistance, a capacitor C′ corresponds to a coupling capacitance between the antenna device 101 and the medium (pseudo phantom PB), and a resistor R′ corresponds to a loss caused by the medium (pseudo phantom PB).

The antenna is thus expressed by an equivalent circuit formed by an LC resonator and a resistor including a loss and a radiation resistance. The antenna device and the housing form a dipole system, and thus are expressed by a series resonant circuit. The human body (including the hands and body) is a low-permittivity dielectric. As an electric field is captured by the human body when the human body comes into proximity of the antenna, energy is consumed in the human body (although the electric field is incident to the human body, the electric field energy is dispersed as the heat, since the human body is a lossy medium).

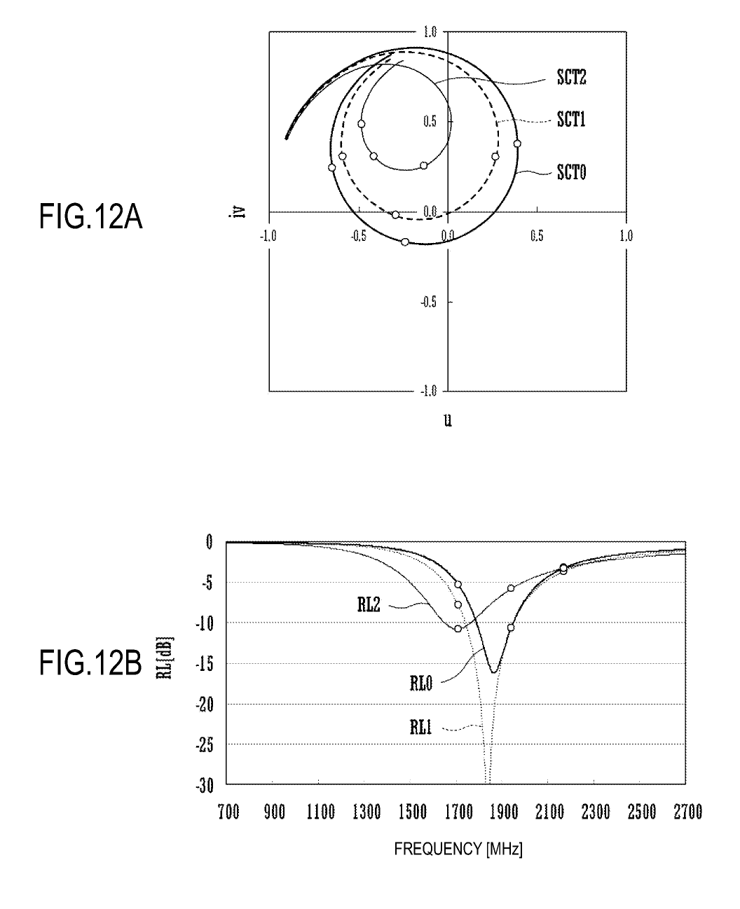

FIG. 12A is a diagram illustrating an impedance locus on a Smith chart in the equivalent circuit illustrated in FIG. 11. FIG. 12B is a diagram illustrating the return loss thereof.

In FIG. 12A, a locus SCT0 represents a small circle locus in a free state, a locus SCT1 represents a small circle locus in a state in which only the pseudo phantom PB is present, and a locus SCT2 represents a small circle locus in a state in which the pseudo phantoms PH and PF (hand only) are present.

In FIG. 12B, a curve RL0 represents a return loss in the state in which there is no covering by a hand, a curve RL1 represents a return loss in the state in which only the pseudo phantom PB is present, and a curve RL2 represents a return loss in the state in which the pseudo phantoms PH and PF are present.

As obvious from comparison of FIGS. 12A and 12B with FIGS. 10A and 10B, the drawings are substantially approximate to each other in terms of the impedance locus on the Smith chart and the return loss characteristic. It is considered from this that the above-described assumed process expresses the actual phenomenon. That is, it can be presumed that the reduction in size of the circle by the proximity of the human body is a phenomenon attributed to the addition of a human body loss via a coupling electric field.

Therefore, the antenna matching circuit in accordance with the present disclosure is capable of, when causing the capacitor C2 of the matching section M to move the small circle locus formed in the first quadrant of the Smith chart to the proximity of the center (50Ω), handling (1) the transition of the state from “absence” to “presence” of the influence of the human body and (2) the expansion of the band at the time of switching of the frequency band, by using a common (shared) architecture.

Subsequently, description will be made of the switching of the resonant frequency of the antenna by the reactance changing section RC.

To perform the switching of the resonant frequency, such as the switching between the low band and the high band, it is necessary to change the resonant length (=electrical length) of the antenna including the antenna element per se and the reactance component of the reactance changing section RC connected to the base of the antenna element. The reactance changing section RC is formed by the combination of an inductor (jωL) and a capacitor (1/jωC), and jX (reactance) as a whole thereof determines the reactance amount. The most common configuration is an LC resonant circuit.

In general, it is difficult to realize a variable inductor, but it is highly possible to realize a variable capacitor. With the reactance changing section RC formed by an LC resonant circuit of a variable capacitor and a fixed inductor, therefore, the architecture is easy to realize.

In a second exemplary embodiment, the selection of an antenna having favorable radiation Q will now be described.

As a conclusion, the efficiency obtained by the application of the antenna matching circuit of the present disclosure relies on the radiation Q possessed by the antenna (antenna [as a pseudo dipole] including an antenna element not including a matching circuit other than a load reactance for bringing the resonant frequency to a desired frequency band and a housing portion contributing to the radiation) per se. An antenna having radiation Q as favorable (small in value) as possible should be selected as this antenna.

The second exemplary embodiment is intended to experimentally verify this effect.

First, two types of antennas different in radiation Q were prepared. The antenna matching circuit was applied to each of the antennas, and the characteristics of the antennas were measured.

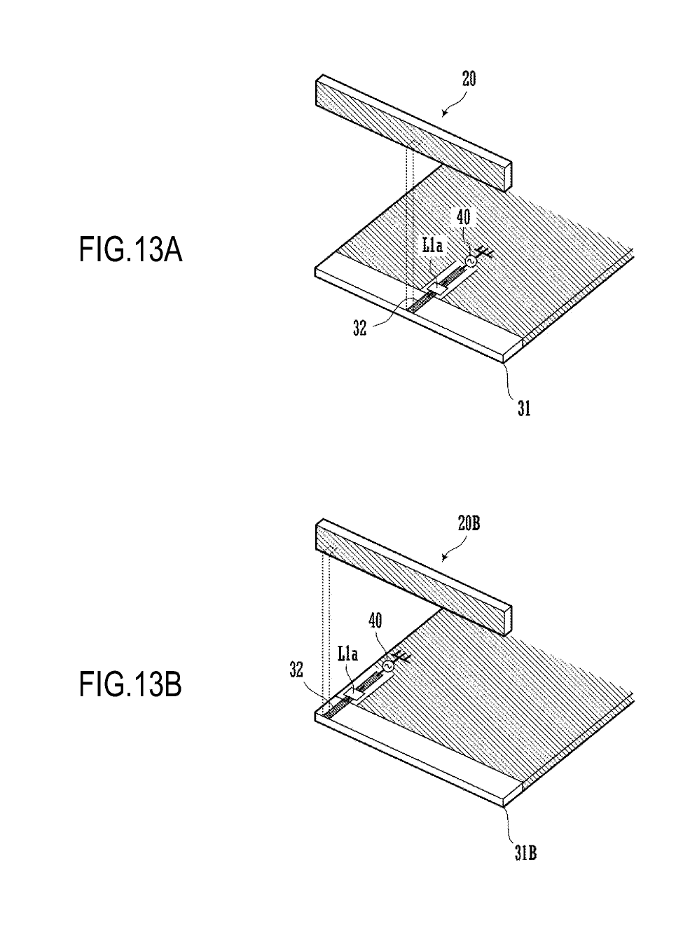

FIGS. 13A and 13B are perspective views of the two types of antennas. Both examples of FIG. 13A and FIG. 13B are configured such that a load reactance L1a is inserted between the antenna connecting section 32 and the feed circuit 40 to bring the resonant frequency to a desired value, and that the feed position is changed relative to the antenna element 20.

The example in FIG. 13A is configured such that the antenna connecting section 32 is disposed at a central portion of the board 31 and connected to the center-fed antenna element 20. Further, the example in FIG. 13B is configured such that the antenna connecting section 32 is disposed at an end portion of a board 31B and connected to an end-fed antenna element 20B.

The radiation Q values of the above-described two types of antennas are as follows:

Center-Fed Antenna

Low band: 8.4

High band: 25.4

End-Fed Antenna

Low band: 9.8

High band: 35.8

With this center-fed configuration, favorable (small in value) radiation Q of the antenna is obtained.

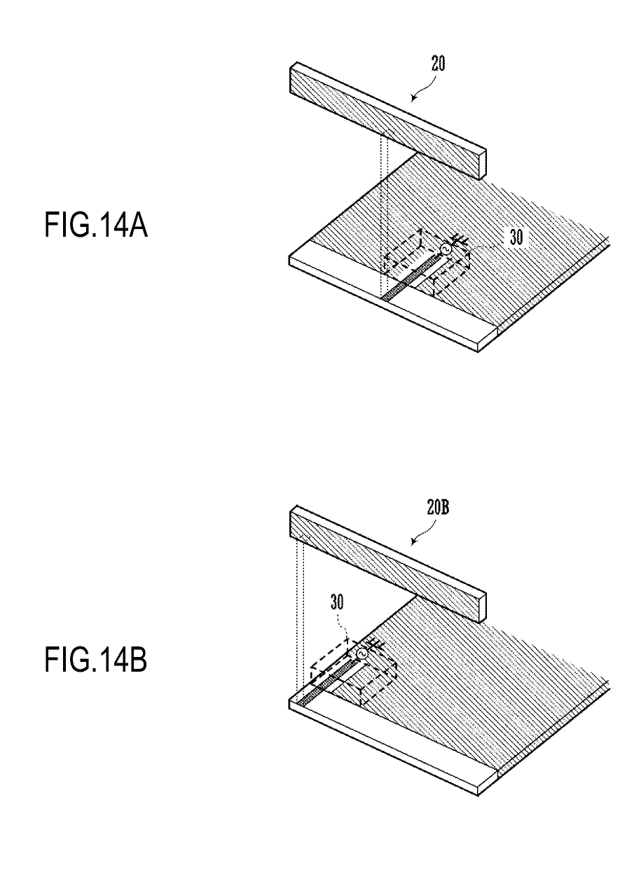

FIGS. 14A and 14B illustrates examples of application of the antenna matching circuit 30 described in the first exemplary embodiment to the antennas illustrated in FIGS. 13A and 13B.

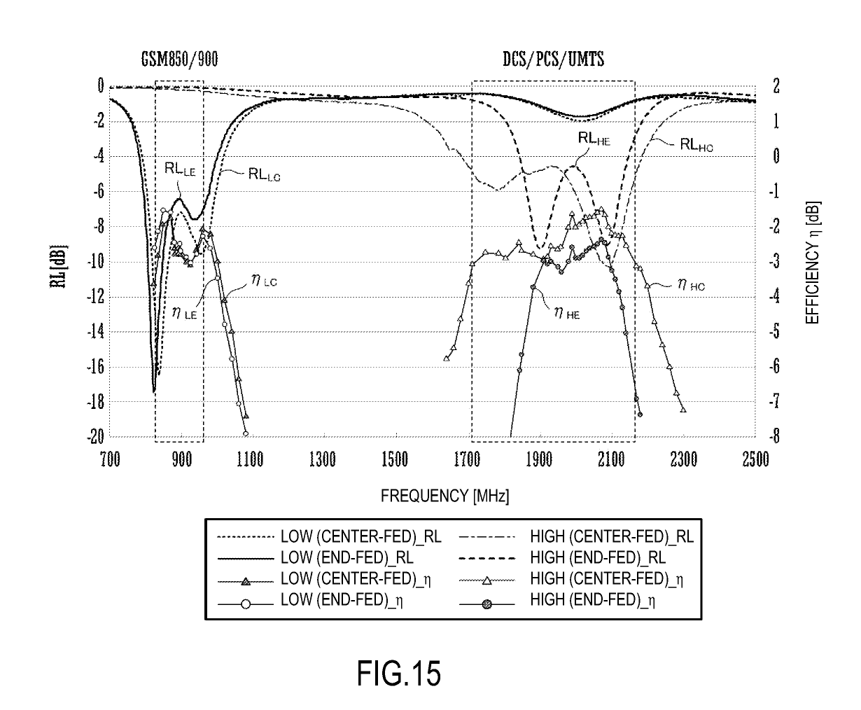

Further, FIG. 15 illustrates return losses and efficiencies of the respective antennas obtained after the application of the antenna matching circuit 30. Herein, the low band is a GSM850/900 frequency band, and the high band is a DCS/PCS/UMTS frequency band. The average efficiencies in the respective bands are as follows:

RL_{LC}: return loss of low-band side center-fed antenna

RL_{LE}: return loss of low-band side end-fed antenna

η_{LC}: efficiency of low-band side center-fed antenna

η_{LE}: efficiency of low-band side end-fed antenna

RL_{HC}: return loss of high-band side center-fed antenna

RL_{HE}: return loss of high-band side end-fed antenna

η_{HC}: efficiency of high-band side center-fed antenna

η_{HE}: efficiency of high-band side end-fed antenna

Center-Fed Antenna:

Low band: −2.6 (dB)

High band: −2.3 (dB)

End-Fed Antenna:

Low band: −2.4 (dB)

High band: −3.9 (dB)

In the example illustrated in FIG. 15, however, the board length D in FIG. 2A is set to 100 mm. Further, the capacitor does not have a variable capacitance, and is replaced by a discrete element for the experiment. Further, this comparison of characteristics is performed in free space.

If the antenna matching circuit is thus loaded, the ability of the radiation Q of the antenna is reflected. The more favorable (smaller in value) the radiation Q of the antenna is, the higher efficiency characteristic is obtained.

In this example, the current flowing through the housing is high in proportion (high in degree of dependence) in the low frequency band. Therefore, there is no difference in the radiation Q of the antenna including the housing, which is not suitable for this verification.

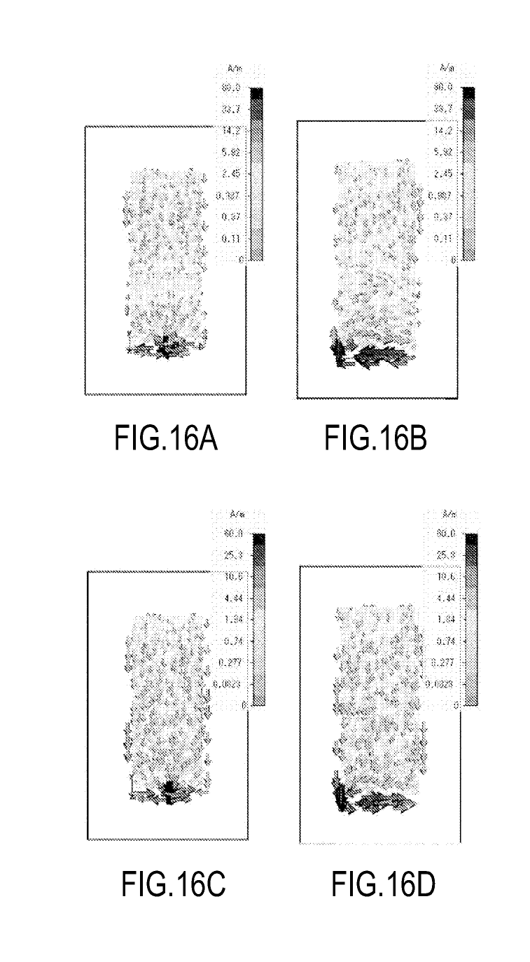

FIGS. 16A to 16D illustrate the results of simulations, for the two types of antennas, of the intensity distribution of surface current flowing through the housing. FIG. 16A and FIG. 16C illustrate current distributions in different frequency bands in the example of the center-fed antenna, and FIG. 16B and FIG. 16D illustrate current distributions in different frequency bands in the end (left end in the drawings)-fed antenna. FIG. 16A illustrates the high band of the center-fed antenna. FIG. 16B illustrates the high band of the end-fed antenna. FIG. 16C illustrates the low band of the center-fed antenna. FIG. 16D illustrates the low band of the end-fed antenna.

As apparent from the high band of the center-fed antenna illustrated in FIG. 16A, the current flows over the entirety of the left and right sides with no imbalance in the intensity distribution of the current. Meanwhile, in the high band of the end-fed antenna illustrated in FIG. 16B, there is imbalance between the left and right sides in the intensity distribution of the current. It is understood that, particularly on the left side, the current intensity is low and the radiation Q of the antenna (antenna formed by an antenna element not including a matching circuit other than a load reactance for bringing the resonant frequency to a desired frequency band and a housing portion contributing to the radiation) is unfavorable.

In this second exemplary embodiment, the center-fed antenna and the end-fed antenna have been compared to show that an antenna having favorable radiation Q should be selected. However, the radiation Q also varies depending on the interval between the antenna element and the ground facing the antenna element and the size of the antenna element, as well as the feed type. Therefore, an antenna element having favorable (small in value) radiation Q should be selected with one or various combinations of a plurality of these as a selection condition.

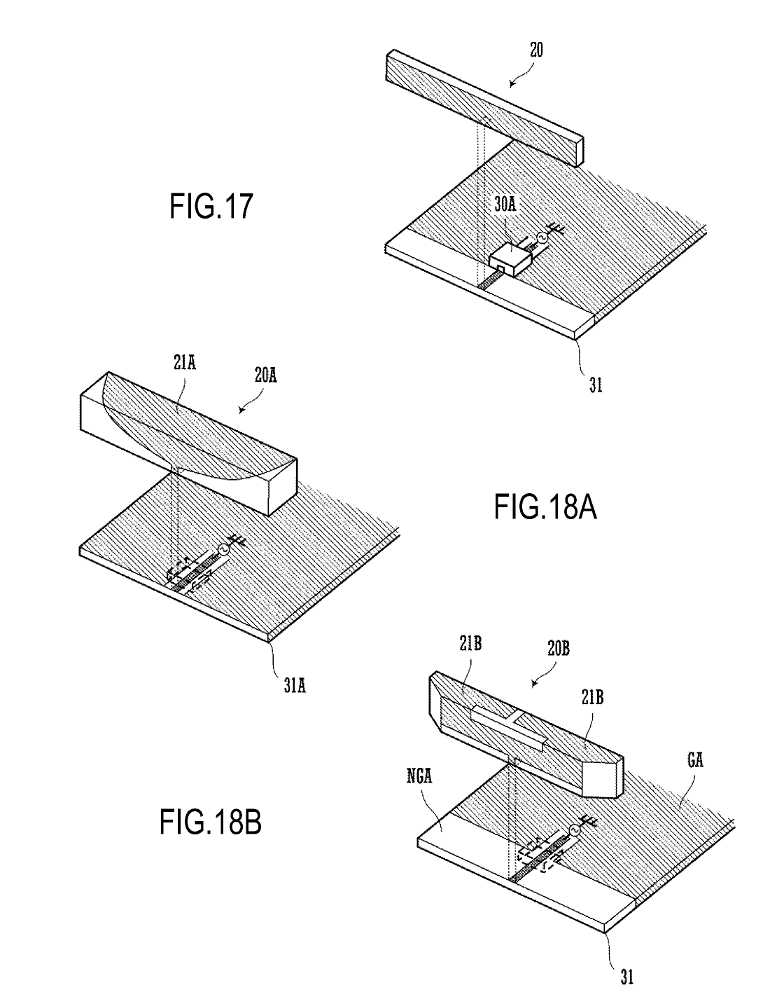

FIG. 17 is an exploded perspective view illustrating a configuration of an antenna device according to a third exemplary embodiment.

FIG. 17 illustrates an example in which the antenna matching circuit 30 exactly illustrated in FIG. 2A in the first exemplary embodiment is configured as a packaged antenna matching circuit module 30A and mounted on the board 31.

This antenna matching circuit module 30A corresponds to the antenna matching circuit 30 illustrated in FIGS. 2A and 2B formed by the use of, for example, an LTCC (low temperature co-fired ceramics) multilayer board. With this configuration, it is possible to reduce the number of components and efficiently use the space of the board 31.

In a fourth exemplary embodiment, several examples that are different in the antenna element and the antenna element electrode will now be described.

FIG. 18A is an exploded perspective view of an antenna device according to the fourth exemplary embodiment. On a surface of a dielectric substrate having a rectangular parallelepiped (rectangular column) shape, an antenna element 20A is used which is formed with an antenna element electrode 21A spreading in a funnel shape as illustrated in the drawing. With this formation of the antenna element electrode 21A having a pattern in which the antenna element electrode 21A gradually spreads from the feed section of the antenna element 20A, resonance occurs at ¼ wavelength over a wide frequency band, and the expansion of the band is promoted.

Further, in the example illustrated in FIG. 18A, only an electrode for the antenna connecting section is formed on the bottom surface of the antenna element 20A, and the antenna element 20A has a certain volume. It is therefore possible to directly mount the antenna element 20A in the ground area of the board 31A.

FIG. 18B is an exploded perspective view of another antenna device according to the fourth exemplary embodiment. On a surface of a dielectric substrate having a substantially rectangular parallelepiped shape, an antenna element 20B is used, which includes an antenna element electrode 21B divided by a slit at the center as illustrated in the drawing. Thus divided by the slit, the antenna element electrode 21B acts as an antenna element for the low band with the fundamental wave of the antenna element electrode, and acts as an antenna element for the high band with the second harmonic wave of the antenna element electrode. Alternatively, one of the divided elements acts as an antenna element for the low band, and the other one of the divided elements acts as an antenna element for the high band.

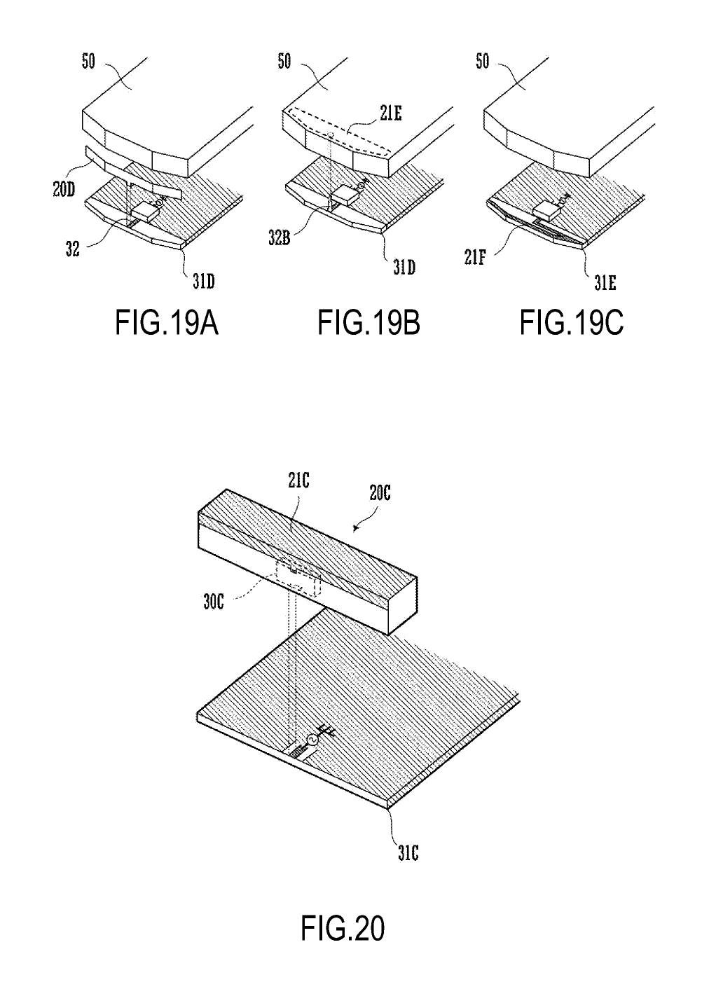

FIG. 19 is exploded perspective views of three other exemplary antenna devices. The example in FIG. 19A uses an antenna element 20D formed by a folding-processed metal plate, solders this to or brings this into spring contact with the antenna connecting section 32 formed on a board 31D, and covers an upper portion thereof with a housing 50. End portions of the antenna element 20D and the board 31D are formed into a shape fitting the shape of the housing 50 and not forming unnecessary space.

The example in FIG. 19B attaches a (spring) pin-like antenna connecting section 32B to the board 31D, and provides an antenna element electrode 21E to the inner surface of the housing 50 such that the antenna connecting section 32B is connected to the antenna element electrode 21E with the housing 50 covering the board 31D. The application to the configuration having the antenna element thus provided to a portion of the housing is also possible.

The example in FIG. 19C directly forms an antenna element electrode 21F in a non-ground area NGA of a board 31E. In this manner, a board pattern may also serve as the antenna element.

FIG. 20 is an exploded perspective view of two antenna devices according to a fifth exemplary embodiment.

The example of FIG. 20 forms an antenna element electrode 21C on an antenna element 20C, and forms an antenna matching circuit 30C inside a dialectic substrate. Therefore, a board 31C, on which this antenna element 20C is mounded, may simply be provided with a feed circuit.

In the respective exemplary embodiments described above, the antenna matching circuit is provided for two frequency bands of the low band and the high band. To adapt the antenna matching circuit to three or more frequency bands, the respective circuit constants of the reactance changing section and the matching section may be set in accordance with the respective frequency bands.

Further, the antenna element is not limited to the electrode pattern formed on a dielectric substrate, and may be configured as an electrode pattern formed on a magnetic substrate.

Further, the configuration of the antenna element electrode and the interface between the antenna element electrode and the conductor pattern on the board are not limited to the respective embodiments described above, and other publicly known configurations may be employed.

Further, the target of reconfiguration is not limited to the switching between the low band [GSM800/900] and the high band [DCS/PCS/UMTS]. The target may be a case in which another system (such as WLAN, Bluetooth, or Wimax) is added, or a case in which Pentaband is covered by the division into finer frequency bands. In that case, the capacitance value to be prepared will be finely set.

Further, the antenna element may be assigned with the fundamental wave and the harmonic wave, or may have a reactance element inserted in the element and have resonance points in a plurality of bands.

Further, in the exemplary examples described above, the reactance changing section is formed by a parallel LC resonant circuit, but is not limited thereto. The reactance changing section may be any configuration capable of, as a whole, changing the reactance, and may be an LC series resonant circuit or an LC resonator added with an extra discrete element, such as in Patent Document 3 (Japanese Unexamined Patent Application Publication No. 2008-113233).

Further, the inductor of the LC resonator in the reactance changing section and the inductor of the matching section are not limited to the discrete element, and may be replaced by, for example, a line pattern.

Further, description has been made that the inductor of the matching section is fixed to a common value (intermediate [compromising] value between the low band and the high band) to save the switching operations as much as possible. To achieve an optimal inductance value for each band, however, the inductor can be configured as a variable inductor. An LC resonant circuit can be formed therefor.

Further, the variable capacitor may be formed by an MEMS (Micro Electro Mechanical Systems) switch.

Embodiments consistent with the disclosure can make it is easy to change, in accordance with the required antenna characteristics, the characteristics of the antenna matching circuit on the basis of the selection of circuit elements.

Some or all of circuit elements forming the antenna matching circuit can be packaged on or in a laminated board, for example. Thereby, it is possible to handle the circuit elements as a component mountable on a circuit board on which the antenna matching circuit is to be mounted, and to reduce the occupied area on the circuit board.

An antenna device of the present disclosure can include an antenna matching circuit having one of the abovementioned configurations and the antenna element. Thereby, a reconfigurable and adjustable antenna device is obtained.

The antenna element can be formed by a dielectric or magnetic substrate and an antenna element electrode disposed on a surface of the substrate or inside the substrate, for example. With this configuration, as well as compactness of the element, compactness of the whole unit is attained owing to the lack or reduction of the need to mount components for the antenna matching circuit on a circuit board on which the antenna matching circuit is to be mounted.

The antenna element can be formed by a dielectric or magnetic substrate and an antenna element electrode disposed on a surface of the substrate or inside the substrate, for example. With this configuration, as well as compactness of the element, compactness of the whole unit is attained owing to the lack or reduction of the need to mount components for the antenna matching circuit on a circuit board on which the antenna matching circuit is to be mounted.

The antenna matching circuit can be included in the substrate, for example. With this configuration, compactness of the whole unit is attained owing to the lack or reduction of the need to mount components for the antenna matching circuit on a circuit board on which the antenna matching circuit is to be mounted.

The antenna element can be an antenna element having favorable radiation Q alone as the antenna element, among plural types of antenna elements connectable to an antenna connecting section of the antenna matching circuit. With this configuration, it is possible to form a highly efficient antenna device by connecting an antenna having favorable radiation Q to the antenna matching circuit.

A selection condition of the plural types of antenna elements can be one or various combinations of a plurality of the position of a feed point for the antenna element, the interval between the antenna element and the ground facing the antenna element, and the size of the antenna element. Thereby, it is possible to easily and reliably select the antenna element having favorable radiation Q, and to form a highly efficient antenna device.

According to the present invention, it is possible to configure, in a single matching circuit and with ease, the switching function for compactness and multiband compatibility (reconfigurable function) and the function handling the deviation of matching caused by the influence of the human body (adjustable function).

While exemplary embodiments have been described above, it is to be understood that variations and modifications will be apparent to those skilled in the art without departing from the scope and spirit of the disclosure.

What is claimed is:

1. A method of designing an antenna device including an antenna element and an antenna matching circuit connected between the antenna element and a feed section, the method comprising:
forming the antenna matching circuit with a reactance changing section connected to a base portion of the antenna element and a matching section connected between the feed section and the reactance changing section; and
forming the matching section with a parallel inductor and a parallel capacitor each shunt-connected between the feed section and ground, wherein
the reactance changing section is switchable to one of plural resonant frequencies compatible with respective plural frequency bands, and finely adjustable in response to a change in the switched resonant frequency caused by the influence of the human body,
the parallel inductor is set to cause the locus of impedance as viewed from the feed section toward the antenna matching circuit to draw a small circle locus in substantially the first quadrant of a Smith chart, and
the capacitance of the parallel capacitor is adjustable to move the small circle locus to the center on the Smith chart.

2. An antenna matching circuit connected between an antenna element and a feed section, comprising:
a reactance changing section connected to a base portion of the antenna element; and
a matching section connected between the feed section and the reactance changing section, wherein
the matching section is formed by a parallel inductor and a parallel capacitor each shunt-connected between the feed section and ground,
the reactance changing section is adapted to set a reactance value to switch the resonant frequency to be compatible with a plurality of frequency bands and perform fine adjustment of the resonant frequency in response to a change caused by the influence of the human body,
the parallel inductor is set to a value for having the locus of impedance as viewed from the feed section toward the antenna matching circuit draw a small circle locus in substantially the first quadrant of a Smith chart, and
the parallel capacitor is adjustable to set a capacitance value for moving the small circle locus to the center on the Smith chart.

3. The antenna matching circuit described in claim 2, wherein the reactance changing section is an LC resonant circuit of a fixed inductor and a variable capacitor.

4. The antenna matching circuit described in claim 2, wherein some or all of circuit elements forming the antenna matching circuit are packaged on or in a laminated board.

5. The antenna matching circuit described in claim 3, wherein some or all of circuit elements forming the antenna matching circuit are packaged on or in a laminated board.

6. An antenna device comprising the antenna matching circuit described in claim 2 and the antenna element.

7. An antenna device comprising the antenna matching circuit described in claim 3 and the antenna element.

8. An antenna device comprising the antenna matching circuit described in claim 4 and the antenna element.

9. An antenna device comprising the antenna matching circuit described in claim 5 and the antenna element.

10. The antenna device described in claim 6, wherein the antenna element is formed by a dielectric or magnetic substrate and an antenna element electrode disposed on a surface of the substrate or inside the substrate.

11. The antenna device described in claim 7, wherein the antenna element is formed by a dielectric or magnetic substrate and an antenna element electrode disposed on a surface of the substrate or inside the substrate.

12. The antenna device described in claim 8, wherein the antenna element is formed by a dielectric or magnetic substrate and an antenna element electrode disposed on a surface of the substrate or inside the substrate.

13. The antenna device described in claim 9, wherein the antenna element is formed by a dielectric or magnetic substrate and an antenna element electrode disposed on a surface of the substrate or inside the substrate.

14. The antenna device described in claim 10, wherein the antenna matching circuit is included in the substrate.

15. The antenna device described in claim 11, wherein the antenna matching circuit is included in the substrate.

16. The antenna device described in claim 12, wherein the antenna matching circuit is included in the substrate.

17. The antenna device described in claim 13, wherein the antenna matching circuit is included in the substrate.

18. The antenna device described in claim 6, wherein the antenna element is an antenna element having favorable radiation Q alone as the antenna element, among plural types of antenna elements connectable to an antenna connecting section of the antenna matching circuit.

19. The antenna device described in claim 18, wherein a selection condition of the plural types of antenna elements is one or various combinations of a plurality of the position of a feed point for the antenna element, the interval between the antenna element and the ground facing the antenna element, and the size of the antenna element.
